(19) United States
(12) Patent Application Publication
(10) Pub. No.: US 2026/0031822 A1
(43) Pub. Date: Jan. 29, 2026

(54) ALL-DIGITAL PHASE LOCKED LOOP WITH POWER SAVING MODE FOR WIRELESS COMMUNICATION DEVICES

(71) Applicant: Morse Micro Pty. Ltd., Surry Hills NSW (AU)

(72) Inventors: Yingbo Zhu, Surry Hills NSW (AU); Ryan Thompson, Surry Hills NSW (AU)

(21) Appl. No.: 19/261,956

(22) Filed: Jul. 7, 2025

(30) Foreign Application Priority Data
Jul. 23, 2024 (AU) 2024902285

(51) Int. Cl. H03L 7/093; H03L 7/099

(52) U.S. Cl. CPC H03L 7/093; H03L 7/0991

(57) ABSTRACT

Wireless communication devices have an all-digital phase locked loop (ADPLL) including a digital controlled oscillator, a counter, a time to digital converter, a phase detector, and a digital loop filter. The digital controlled oscillator (DCO) generates a DCO output signal (CKV) to synchronize with a reference clock signal (FREF), and the counter generates an integer part from CKV. The time to digital converter detects a time difference between a reduced frequency signal and FREF, where this reduced frequency signal is generated from CKV. The phase detector estimates a fractional part based on the time difference and derives a phase error based on the integer part from the counter, the fractional part, and a goal frequency. The digital loop filter receives the phase error and provides tracking codes to the DCO to adjust the frequency of its output signal.

### CROSS REFERENCE TO RELATED APPLICATION

The present application claims priority from Australian provisional patent application number 2024902285 filed on 23 Jul. 2024, the contents of which are incorporated herein by cross-reference.

### FIELD OF THE INVENTION

The present disclosure generally relates to a phase locked loop (PLL). Specifically, aspects of the present disclosure are related to power saving in all-digital phase locked loop (ADPLL).

### BACKGROUND

Recent advancements in wireless technology have facilitated the transition of radio frequency (RF) and analog components into the digital domain, enabling the development of Internet of Things (IoT) and ultra-low-power products. One significant innovation in this domain is the all-digital phase locked loop (ADPLL), which replaces the conventional analog phase locked loop (PLL). A PLL is a critical circuit widely used to achieve accurate frequency synthesis and signal synchronization by generating stable, high-frequency clock signals that are phase-aligned with a reference signal. The ADPLL not only improves power efficiency but also enhances frequency modulation capabilities, improves control and testability, and enables efficient scaling to advanced complementary metal oxide semiconductor (CMOS) nodes. In an RF transmitter, an ADPLL is used to synthesize carrier frequencies for modulation by generating a precise system clock signal that is mixed with the baseband signal to upconvert it to the desired RF frequency. Similarly, in a receiver, an ADPLL generates a system clock signal for down-conversion of the received RF signal to baseband or intermediate frequency. The precise digital control in ADPLLs enables fast frequency hopping, fractional-N synthesis, and low phase noise operation. A single ADPLL can be shared or replicated for both the transmitter and receiver paths in the wireless transceiver.

A phase locked loop is a critical feedback system used for signal synchronization in terms of both frequency and phase, playing an essential role in digital communication. Unlike traditional PLLs, an ADPLL consists entirely of digital components and their digital equivalents. The main functional blocks of an ADPLL typically include a counter, a time-to-digital converter (TDC), a phase detector, a digital loop filter (DLF), and a digitally controlled oscillator (DCO). The TDC in the ADPLL is responsible for measuring the time difference between a reference clock signal (FREF) and a DCO output signal (CKV) by quantizing time intervals between pulses of these two signals. The reference clock signal (FREF) is a locally generated high-precision clock, typically operating at a lower frequency than the DCO output signal (CKV). The CKV, on the other hand, is a high-frequency clock signal generated by the DCO capable of synthesizing the carrier frequency required for modulation and demodulation in RF transmission. The TDC-measured time interval, along with a counter output, is used to synchronize the ADPLL by adjusting the DCO capacitance to achieve a target frequency set by the frequency control word (FCW). Typically, the CKV frequency is equal to or higher than the local oscillator (LO) frequency. For example, for a wireless communication system receiving and transmitting signals at sub-gigahertz (SIG) radio spectrum, the CKV frequency is often twice that of the LO frequency. For an RF signal transmitting at 920 MHZ, the CKV frequency required for the ADPLL in the RF transmitter would be set to 1.84 GHZ.

The TDC and DCO are the primary contributors to the overall phase noise performance of the ADPLL, with the TDC often being the most power-intensive component in the ADPLL. The present invention introduces a novel ADPLL design aimed at significantly reducing power consumption while maintaining high accuracy and performance, thereby enhancing the efficiency of ADPLL-based wireless communication systems.

### SUMMARY

The following summary presents technical features relating to one or more aspects of disclosed herein and should not be considered as an extensive overview relating to all contemplated aspects. Accordingly, the following summary has the sole purpose to present certain concepts relating to one or more embodiments relating to packet detection disclosed herein in a simplified form to precede the detailed description presented below.

An all-digital phase locked loop (ADPLL) generates a system clock that is phase-aligned with a reference clock signal (FREF). The ADPLL includes a digitally controlled oscillator (DCO), a counter, a time-to-digital converter (TDC), a phase detector, and a digital loop filter (DLF). The DCO generates a DCO output signal (CKV) to synchronize with the reference clock signal. The counter generates an integer part of a phase error from the DCO output signal. The TDC detects a time difference between a reduced frequency signal and the reference clock signal. The reduced frequency signal is generated from the DCO output signal and has a lower frequency than a frequency of the DCO output signal. The phase detector receives the integer part of the phase error from the counter and the time difference from the TDC, estimates a fractional part of the phase error based on the time difference, and derives the phase error based on the integer part of the phase error, the fractional part of the phase error, and a goal frequency set by a frequency control word (FCW). The DLF receives the phase error from the phase detector and provides tracking codes to the DCO. The DCO takes the tracking codes to adjust the frequency of the DCO output signal and lock the DCO output signal in synchronization with the reference clock signal.

Some embodiments of the ADPLL comprise a D-type flip flop (DFF) for generating the reduced frequency signal from the DCO output signal and the reference clock signal. An embodiment of the reduced frequency signal is a CKV snapshot signal carrying information of a rising edge of the DCO output signal with respect to each sampling point of the reference clock signal. For example, the DFF generates the CKV snapshot signal by latching the DCO output signal using the reference clock signal to capture the rising edge of the DCO output signal subsequently after each rising edge of the reference clock signal. The phase detector detects a TDC rising edge (TDC′_{RISE}) from a TDC output and calculates the fractional part of the phase error by multiplying the TDC rising edge and a TDC gain (KTDC). In another example, the CKV snapshot signal captures the rising edge of the DCO output signal immediately preceding each sampling point of the reference clock signal. The phase detector detects a TDC rising edge (TDC_{RISE}) from a TDC output and calculates the fractional part of the phase error by one minus a multiplication of the TDC rising edge and a TDC gain (KTDC).

In some embodiments, the TDC detects a time difference between the DCO output signal and the reference clock signal when operating in a normal mode, whereas the TDC detects a time difference between the reduced frequency signal and the reference clock signal when operating in a power saving mode. For example, the TDC operates in a normal mode during ADPLL locking process and the TDC switches from the normal mode to power saving mode once the ADPLL is locked. In one embodiment, the phase detector includes a fractional phase error estimation block, decoding a TDC output to identify a TDC falling edge (TDC_{FALL}) and a TDC rising edge (TDC_{RISE}), and computing the fractional part of the phase error based on the TDC falling edge and TDC rising edge when the TDC is operating in the normal mode. The fractional phase error estimation block estimates a TDC gain (KTDC) from the TDC falling edge and the TDC rising edge, derives a fixed TDC gain from the estimated TDC gain, and computes the fractional part of the phase error using the fixed TDC gain when the TDC is operating in the power saving mode. For example, the fractional phase error estimation block derives the fixed TDC gain by averaging a predetermined number of previously estimated TDC gains.

An embodiment of the TDC is composed of N-stage inverter chain, and the time difference detected by the TDC is an N-bit pseudo thermometer code. The phase detector comprises a thermometer decoder identifying a 1-to-0 bit transition in the N-bit pseudo thermometer code to generate a TDC rising edge (TDC′_{RISE}), and a multiplier multiplying the TDC rising edge with a TDC gain (KTDC) to generate the fractional part of the phase error. In some embodiments, the reduced frequency signal is generated by capturing a rising edge of the DCO output signal after each sampling point of the reference clock signal, and the TDC rising edge generated by the thermometer decoder represents a time difference measured between a sampling point of the reference clock signal and the subsequent rising edge of the reduced frequency signal.

In some embodiments, the TDC comprises an input selection circuit dynamically selecting two TDC inputs from the reduced frequency signal and the reference clock signal or the DCO output signal and the reference clock signal depending on an enable signal. The ADPLL comprises a DFF coupled to the DCO to reclock the reference clock signal using the DCO output signal to produce the system clock for the ADPLL. The wireless communication device including the ADPLL may further comprise a baseband processor communicatively coupled to the ADPLL to receive the system clock for modulation or demodulation.

In an aspect of the present invention, a method of clock locking by an ADPLL for a wireless communication device comprises receiving a reference clock signal, locking a DCO output signal (CKV) to synchronize with the reference clock signal based on tracking codes; generating a reduced frequency signal from the DCO output signal, generating a TDC output by detecting a time difference between the reduced frequency signal and the reference clock signal, deriving an integer part of a phase error from the DCO output signal and estimating a fractional part of the phase error based on the TDC output, deriving the phase error based on the integer part and fractional part of the phase error, and a goal frequency set by a FCW, generating the tracking codes based on the derived phase error. In some embodiments, the method further comprises reclocking the reference clock signal using the DCO output signal to produce a system clock for the ADPLL. The reduced frequency signal has a lower frequency than a frequency of the DCO output signal, for example, the reduced frequency signal is a CKV snapshot signal carrying information of a rising edge of the DCO output signal with respect to each sampling point of the reference clock signal. In some embodiments, the step of generating a TDC output comprises detecting a time difference between the reduced frequency signal and the reference clock signal when operating in a power saving mode and detecting a time difference between the DCO output signal and the reference clock signal when operating in a normal mode.

Other objects and advantages associated with the aspects disclosed herein will be apparent to those skilled in art based on the accompanying drawings and detailed description.

### BRIEF DESCRIPTION OF THE DRAWINGS

Illustrative aspects of the present application are described in detail below with reference to the following drawing figures:

FIG. 1 illustrates an architecture of a TDC composed of a 64-stage inverter chain.

FIG. 2A illustrates an example of deriving both a TDC rising edge and a TDC falling edge based on a digitally controlled oscillator output signal (CKV) and a reference clock signal (FREF) for fractional phase error computation in an ADPLL.

FIG. 2B illustrates an example of only deriving a TDC rising edge based on a digitally controlled oscillator output signal (CKV) and a reference clock signal (FREF) for fractional phase error computation in an ADPLL.

FIG. 3 illustrates an example of generating a CKV snapshot signal and deriving a new TDC rising edge based on the CKV snapshot signal and FREF for fractional phase error computation in an ADPLL according to an embodiment of the present invention.

FIG. 4 is a block diagram illustrating an embodiment of an input configuration for a TDC capable of operating in one of normal and power saving modes.

FIG. 5 illustrates an example of deriving a TDC rising edge based on the CKV snapshot signal and FREF for fractional phase error computation in an ADPLL according to an embodiment of the present invention.

FIG. 6 is a block diagram illustrating an embodiment of an ADPLL operating in normal or power saving mode.

FIG. 7A is a block diagram illustrating a fractional phase error (PHF) estimation block in the phase detector of an ADPLL operating in one of normal and power saving modes according to an embodiment of the present invention.

FIG. 7B is a block diagram illustrating a fractional phase error (PHF) estimation block in the phase detector of an ADPLL operating in power saving mode according to another embodiment of the present invention.

FIG. 8 is an exemplary block diagram of a wireless communication device that can be a station (STA) or Access Point (AP) implementing an embodiment of the present invention.

FIG. 9 is a flowchart illustrating an embodiment of locking a digitally controlled oscillator output signal (CKV) to synchronize a reference clock signal (FREF) by an ADPLL capable of operating in power saving mode.

### DETAILED DESCRIPTION

Certain aspects and embodiments of this disclosure are provided below. Some of these embodiments may be applied independently and some of them may be applied in conjunction as would be apparent to those of skill in the art. In the following description, for the purposes of explanation, specific details are set forth to provide a thorough understanding of aspects of the application. However, it will be apparent that various embodiments may be practiced without these specific details. The figures and description are not intended to be restrictive. The following description of the embodiments will provide those skilled in the art with an enabling description for implementing an example aspect. Changes may be made in the function and arrangement of elements without departing from the spirit and scope of the application as set forth in the claims.

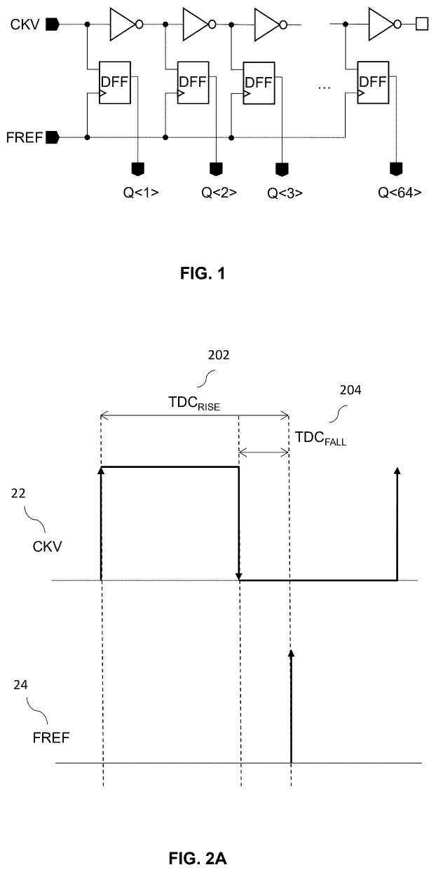

A linear time-to-digital converter (TDC) is a delay-line-based digital circuit designed to convert time differences between two input signals into digital values. For a TDC in an all-digital phase locked loop (ADPLL), the two input signals include a reference clock signal (FREF) and a digitally controlled oscillator (DCO) output signal. The DCO output signal is denoted by CKV in this specification. In one embodiment, a linear TDC operates by passing the CKV pulses through a 64-stage inverter chain, where each inverter introduces a delay of Td. The outputs of these inverters are then latched by FREF, generating a pseudo thermometer code. FIG. 1 illustrates an exemplary TDC architecture featuring a 64-stage inverter chain, where the total delay introduced by the TDC amounts to 64×Td. Due to the high operating frequency of CKV, the TDC delay chain exhibits significant power consumption. For example, when implemented using a 22 nm process in CMOS metal oxide semiconductor filed effect transistor (MOSFET) fabrication, the power consumption of the TDC is approximately 5 mW.

The digital core of an ADPLL processes the output of the TDC, which consists of a 64-bit pseudo thermometer code in this embodiment. Prior to ADPLL locking, the digital core identifies both the TDC rising and TDC falling edges from the pseudo thermometer code. Specifically, a phase detector computes a phase error PHE using both the TDC output and a counter output PHI. The counter counts the cycle of the DCO output signal (CKV), and the counter output PHI denotes an 8-bit unsigned code representing an integer part of the phase error. Within the phase detector, a pseudo thermometer decoder decodes the TDC output to locate the TDC falling edge (TDC_{FALL}), represented by a 0-to-1 bit transition, and the TDC rising edge (TDC_{RISE}), represented by a 1-to-0 bit transition. The pseudo thermometer decoder identifies and labels the first 0-to-1 bit transition as TDC_{FALL}, and the first 1-to-0 bit transition as TDC_{RISE}. These transitions TDC_{FALL} and TDC_{RISE} detected from the pseudo thermometer code are then provided to estimate a fractional part of the phase error PHF, which is also called a fractional phase error in the following. In certain embodiments, once one set of TDC_{RISE} and TDC_{FALL} is successfully detected, any subsequent transitions in the TDC output may be ignored to reduce processing overhead. A fractional phase error estimation block computes the fractional phase error (PHF) using both the TDC_{RISE} and TDC_{FALL} detected from the pseudo thermometer code according to Equation [1].

$$PHF = 1 - \frac{{TDC}_{RISE}}{2 * \vert {TDC}_{RISE} - {TDC}_{FALL} \vert} \qquad Equation [ 1 ]$$

The TDC gain, denoted as KTDC, is defined by Equation [2]. During the ADPLL locking process, KTDC is dynamically estimated based on both the detected TDC_{RISE} and TDC_{FALL}, which are processed through an infinite impulse response (IIR) low-pass filter (LPF) according to one embodiment. This filtering approach smooths out noise and transient variations, providing a more stable estimate of the TDC gain. Once the ADPLL is locked, KTDC is treated as a fixed value, for example, KTDC is derived by averaging a set of previously estimated KTDC values. In one specific embodiment, the fixed TDC gain KTDC is derived by averaging 256 samples of KTDC values. This averaged KTDC is then used in the computation of the fractional phase error PHF, as described in Equation [3].

$$KTDC = \frac{1}{2 * \vert {TDC}_{RISE} - {TDC}_{FALL} \vert} \qquad Equation [ 2 ]$$

$$PHF = 1 - {TDC}_{RISE} * KTDC \qquad Equation [ 3 ]$$

Upon obtaining a fixed KTDC value, the phase noise at the local oscillator (LO) output may be improved, and the TDC falling edge TDC_{FALL} is no longer required for fractional phase error (PHF) computation. Specifically, after the ADPLL is locked, Equation [3] can be simplified by deriving PHF solely from the TDC rising edge TDC_{RISE}, with the fixed averaged KTDC substituted into the equation.

FIG. 2A illustrates an example of deriving both TDC_{RISE} 202 and TDC_{FALL} 204 to estimate a KTD gain (KTDC) and compute PHF during the ADPLL locking phase. TDC_{RISE} 202 indicates a time difference between a rising edge of the DCO output signal (CKV) 22 and a subsequent sampling point of FREF 24, whereas TDC_{FALL} 204 indicates a time difference between a falling edge of CKV 22 and a subsequent sampling point of FREF 24. In contrast, FIG. 2B shows the simplified post-locking approach, where only TDC_{RISE} 206 derived from a rising edge of CKV 26 with respect to the subsequent sampling point of FREF 28 is used for PHF calculation, leveraging the averaged KTDC value obtained after the ADPLL is locked.

Since only the TDC rising edge (TDC_{RISE}) is required for PHF calculation after ADPLL locking, the TDC no longer needs to process the full CKV pulse train to capture every CKV rising edge in CKV. Instead, it is sufficient for the TDC to capture only the rising edge of CKV with respect to each sampling point of the reference clock signal (FREF). For example, the TDC only captures the first rising edge of CKV occurring after each sampling point of FREF. In another example, the TDC only captures the rising edge of CKV occurring right before each sampling point of FREF. Embodiments of the present invention generate a reduced frequency signal with a lower frequency than CKV carrying information of the TDC rising edges with respect to the sampling points of FREF. For example, CKV is running at 1.84 GHZ for modulation and demodulation of a RF signal transmitted at 920 MHz, whereas FREF is only running at 32 MHz. The reduced frequency signal can run at a frequency as slow as FREF since it only captures one rising edge with respect to each FREF sampling point. The TDC receives this reduced frequency signal (e.g. 32 MHZ) instead of the original high-frequency CKV signal (e.g. 1.84 GHZ) after obtaining a fixed KTDC, which slows down the TDC operation as both the input signals of TDC are now low frequency (e.g. 32 MHZ). In some embodiments, the reduced frequency signal is a CKV snapshot signal, capturing a snapshot of the CKV rising edge relative to each FREF sampling point.

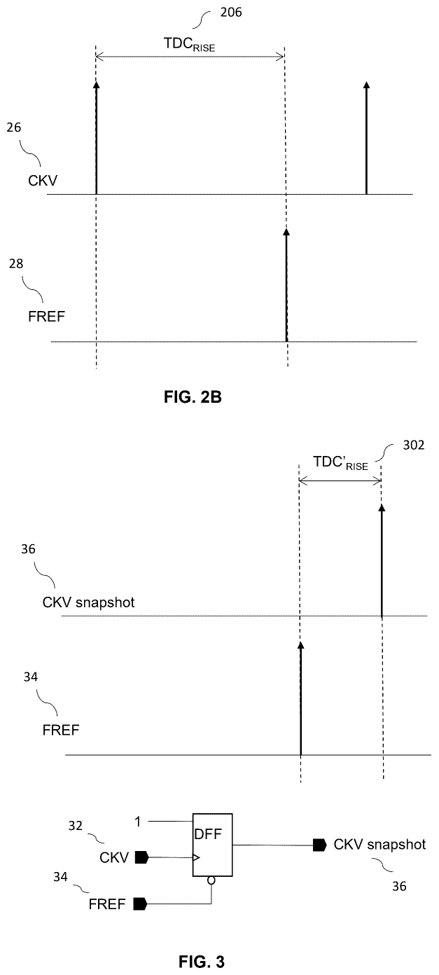

FIG. 3 illustrates an embodiment of generating a CKV snapshot signal 36 by a simple D-type flip-flop (DFF) which captures a rising edge of CKV 32 after each sampling point of FREF 34. The TDC receives the CKV snapshot signal 36 and FREF 34 thus detects a new TDC rising edge 302, denoted TDC′_{RISE}, which is a time difference measured between a sampling point (i.e. a rising edge) of FREF 34 and the subsequent rising edge of the CKV snapshot signal 36. The D-type flip-flop generates the CKV snapshot signal 36 to synchronize CKV 32 with FREF signal 34. In this embodiment, the rising edge of the CKV snapshot signal occurs after the FREF rising edge, the original PHF computation in Equation [3] is modified accordingly. The updated formulation, shown in Equation [4], uses TDC′_{RISE} as illustrated in FIG. 3 in place of the original TDC_{RISE} depicted in FIG. 2A and FIG. 2B.

$$PHF = {TDC}_{RISE}^{′} * KTDC \qquad Equation [ 4 ]$$

An embodiment of the present invention enables the ADPLL to operate in one of two selectable modes: a normal mode and a power saving mode. Depending on the selected mode, different sets of input signals are provided to the TDC in the ADPLL to optimize power efficiency. In the normal mode, the TDC receives the original high-frequency DCO output clock signal (CKV), and the low-frequency reference clock signal (FREF). In contrast, during power saving mode, the TDC inputs are reconfigured to use the low-frequency CKV snapshot signal and low-frequency FREF. The CKV snapshot signal is a signal capturing only the rising edge of CKV relative to each FREF edge, significantly reducing the dynamic activity within the TDC and thereby lowering power consumption of the TDC during the power saving mode.

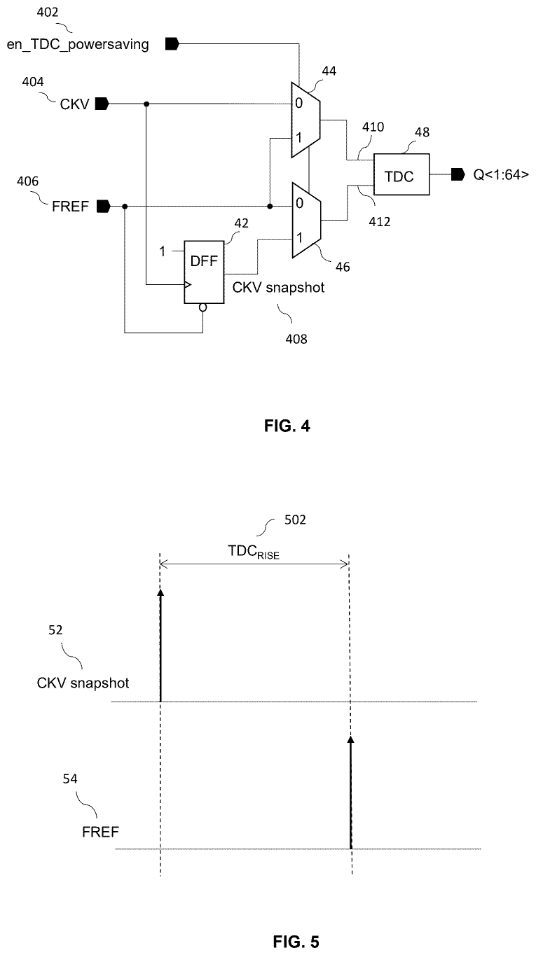

FIG. 4 illustrates an embodiment of the input port configuration for a TDC 48 within the ADPLL RF core. The TDC input selection is controlled by an enable signal 402, en_TDC_powersaving. This enable signal 402 is set to 0 when the TDC 48 is operating in the normal mode, resulting in two multiplexers 44 and 46 routing CKV 404 and FREF 406 to the TDC 48 as TDC_start 410 and TDC_stop 412, respectively. Conversely, when the enable signal 402 is set to 1, indicating the TDC 48 is operating in the power saving mode, the TDC_start 410 is assigned to FREF 406, which propagates through a TDC delay chain, while the CKV snapshot signal 408 serves as TDC_stop 412, used to latch the output of the TDC delay chain. The CKV snapshot signal 408 is generated by the flip-flop DFF 42 from CKV 404 and FREF 406. An example of the TDC delay chain is realized by a 64-stage inverter chain. This dual-mode configuration enables dynamic switching between normal and power saving operations, leveraging the use of a fixed KTDC for PHF calculation after ADPLL locking to reduce power consumption.

When the TDC 48 operates in the power saving mode, both of its input signals are clocked at the frequency of FREF 406. FREF 406 is typically a much slower clock signal, for example, operating at 32 MHz. The use of low-frequency inputs significantly reduces the dynamic switching activity in the TDC delay chain, thereby lowering its power consumption. In some embodiments of the present invention, the TDC 48 initially operates in the normal mode prior to ADPLL locking and then transitions to the power saving mode after a predetermined condition is met. For instance, the transition to the power saving mode may occur after the estimation of a stable average KTDC value, such as the average of 256 KTDC samples, indicating that the ADPLL has reached lock. This approach allows the TDC 48 to remain in the normal mode only for a limited duration during frequency acquisition, and to operate in the power saving mode for the majority of time during steady-state operation. As a result, the ADPLL incorporating this dynamic TDC power management strategy exhibits significantly lower overall power consumption compared to conventional ADPLL architectures that do not implement this feature.

An experiment was conducted using analog-mixed-signal (AMS) simulations to evaluate the performance of an embodiment of the ADPLL incorporating the power saving feature. The transition from the normal mode to power saving mode was triggered by asserting an enabling signal at approximately 210 microseconds (μs). Following this transition, a brief disturbance was observed in the phase error signal, during which the locked status signal was de-asserted for approximately 6 us before being reasserted, indicating recovery of the phase lock. In the power saving mode, the TDC no longer detects the falling edge (TDC_{FALL}) due to the use of the slower CKV snapshot signal, which only provides a rising edge with respect to each FREF sampling point for time interval measurement. Consequently, the shape of the TDC_{RISE} signal exhibits a change in its trajectory, reflecting the difference in phase error computation between Equation [3] and Equation [4]. Schematic-level simulations of the TDC demonstrate a substantial reduction in current consumption when operating in the power saving mode. In this experiment, the TDC current dropped from approximately 4.6 mA in the normal mode to just 0.52 mA in the power saving mode, representing a power saving of over 4 mA.

In another embodiment, the CKV snapshot signal 52 is generated for the TDC to measure the time difference, TDC_{RISE} 502, between the rising edge of a CKV pulse and the subsequent sampling edge of FREF 54, as illustrated in FIG. 5. In this configuration, the detected CKV rising edge 502 corresponds to the clock pulse immediately preceding the FREF sampling point. The calculation of the fractional phase error (PHF) in this embodiment remains consistent with the expression provided in Equation [3]. Furthermore, FREF is routed to the input of the TDC, TDC_stop, for both the normal and power saving modes, the use of a TDC input multiplexer for TDC_stop input signal selection becomes unnecessary. Only one TDC input multiplexer for TDC_start input signal selection is needed to select between CKV and CKV snapshot signals based on the enable signal, thereby further simplifying the overall schematic design and reducing implementation complexity in comparison to the embodiment shown in FIG. 4.

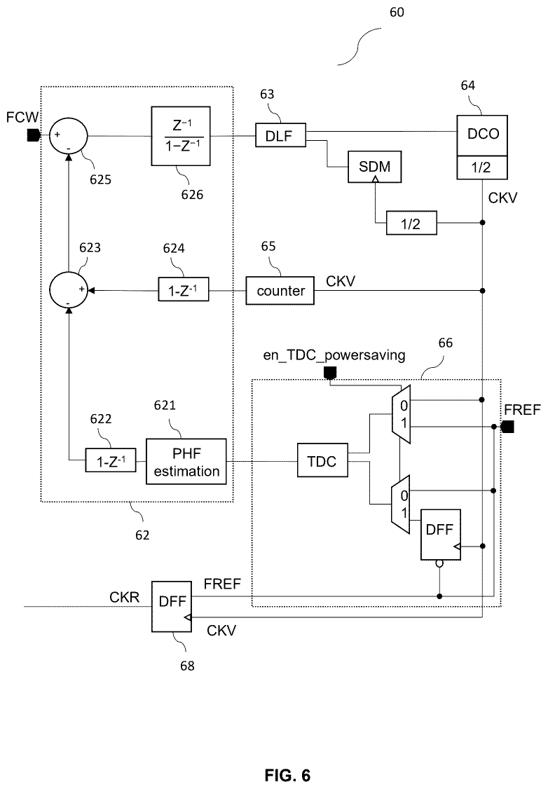

FIG. 6 illustrates a block diagram of an ADPLL 60 according to an embodiment of the present invention. The ADPLL 60 comprises a phase detector 62, a digital loop filter (DLF) 63, a digitally controlled oscillator (DCO) 64, a counter 65, a time-to-digital converter (TDC) block 66, and a D-type flip-flop (DFF) 68. The phase detector 62 receives a pseudo thermometer code output from the TDC block 66 to detect the TDC rising edge and calculates a phase error (PHE) based on the pseudo thermometer code, the counter output (PHI), and the target frequency defined by the frequency control word (FCW). The DLF 63 is coupled with an output of the phase detector to process the phase error PHE and provides tracking codes for the DCO 64. The DCO 64, in turn, generates a high-frequency clock output signal (CKV). The counter 65 monitors the number of CKV pulses within each CKR cycle to compute the integer part of the phase error, which is referred to as the counter output PHI. The DFF 68 reclocks the reference clock signal (FREF) using the CKV signal to produce the system clock (CKR), which provides synchronization across the ADPLL digital blocks. The pseudo thermometer code output from the TDC block 66 is decoded by a fractional phase error estimation block 621 within the phase detector 62 to extract the fractional part of the phase error (PHF), then PHF is differentiated by a differentiator 622 to generate a differentiated fractional component (dPHF). The counter output PHI is also processed by a differentiator 624 in the phase detector 62 to generate a differentiated integer component (dPHI). The differentiated fractional component (dPHF) is combined with the differentiated integer component (dPHI) by an adder 623 and combined with the frequency control word (FCW) by another adder 625 to generate a differentiated phase error (dPHE). The differentiated phase error (dPHE) is then processed by an integrator 626 to generate the phase error (PHE).

Embodiments of the TDC block 66 operate in two modes depending on the state of the enable signal en_TDC_powersaving. In the normal mode, the TDC block 66 receives CKV and FREF and measures the time difference between these signals. In the power-saving mode, the TDC block 66 receives a CKV snapshot signal and FREF, both of which have lower frequencies than the CKV signal. The CKV snapshot signal is generated by a DFF within the TDC block 66 according to the CKV signal, aligned to the rising edge of the FREF signal, thereby reducing dynamic power consumption in the TDC block 66. This dual-mode operation enables the system to maintain precise phase tracking while significantly reducing power consumption after frequency lock is achieved by the ADPLL.

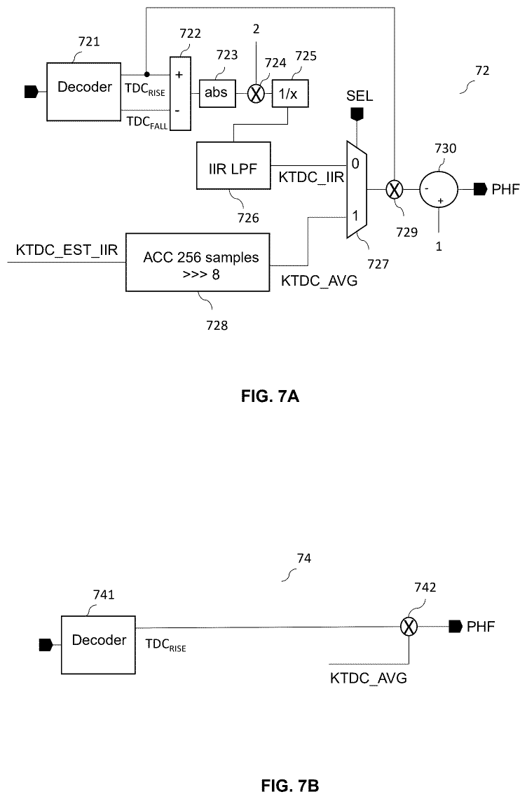

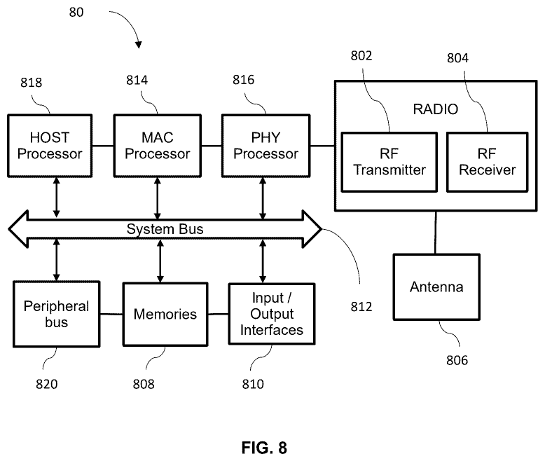

FIG. 7A illustrates a block diagram of a fractional phase error estimation block 72 in the phase detector operating in a normal or power saving mode in accordance with an embodiment of the present invention. In the normal mode, the fractional phase error estimation block 72 calculates the estimated TDC gain (KTDC_EST) from the pseudo thermometer code by a thermometer decoder 721, an adder 722, an absolute block 723, a multiplier 724, and an inversion block 725 according to Equation [2]. This estimated TDC gain is processed through an infinite impulse response low-pass filter (IIR LPF) 726 to smooth variations, and the fractional component of the phase error (PHF) is then computed from the processed TDC gain (KTDC_IIR) using a multiplexer 727, a multiplier 729, and an adder 730 according to Equation [3]. Concurrently, an accumulator 728 in the phase detector 72 accumulates a number of KTDC_EST samples to calculate an average gain value (KTDC_AVG) by summing the individual KTDC values and performing a bitwise shift. For example, the accumulator 728 sums up 256 samples of KTDC values and divides by 256 by bitwise shifting. Once the ADPLL enters the power saving mode, the multiplexer 727 selects the computed average gain value KTDC_AVG as a fixed gain constant to evaluate the fractional phase error (PHF) through the multiplier 729 and adder 730 according to Equation [3]. In this embodiment, the CKV snapshot signal captures the CKV rising edge before the FREF sampling point as shown in FIG. 5. FIG. 7B illustrates a block diagram of a fraction phase error estimation block 74 in the phase detector operating in the power saving mode in accordance with another embodiment of the present invention. The fraction phase error estimation block 74 comprises a thermometer decoder 741 and a multiplier 742. During the power saving mode, the thermometer decoder 741 only detects TDC′_{RISE}, which corresponds to time difference between the FREF sampling point and subsequent the rising edge of CKV. The fractional phase error (PHF) is computed by multiplying the TDC′_{RISE} and the average gain value KTDC_AVG by the multiplier 742 according to Equation [4].

FIG. 8 shows a high-level block diagram of a wireless communication device 80 that includes an ADPLL capable of operating in a power saving mode according to an embodiment of the present invention. The wireless communication device 80 manages a Medium Access Control (MAC) layer and a Physical (PHY) layer in compliance with an IEEE 802.11 standard. The wireless communication device 80 is a Station (STA) or an Access Point (AP) of a wireless network. For example, the wireless communication device 80 is in a mobile device, a personal computer, a laptop computer, an Internet of Things (IoT) device, a wearable device, an extended reality device, a video server, a camera, or a communication device on a vehicle. The wireless communication device 80 includes an RF transmitter module 802, an RF receiver module 804, an antenna unit 806, one or more memory banks 808, input and output interfaces 810 and communication bus 812. The RF transmitter module 802 and the RF receiver module 804 are also known as an RF transceiver. The wireless communication device 80 includes a MAC processor 814, a PHY processor 816, and a HOST processor 818. These processors can be realized by any type of Integrated Circuit (IC) such as a General Processing Unit (GPU), an Application Specific Integrated Circuit (ASIC), or Reduced Instruction Set Computer-Five (RISC-V) based ICs, amongst others. The PHY processor 816 bridges between the MAC layer and the RF front-end and is responsible for modulation and demodulation. Specifically, the frames are transmitted by modulating one or more carrier wave signals to encoded digital information according to a clock signal (e.g. CKV) generated by an ADPLL. Received frames are demodulated to reconstruct the original digital information according to the clock signal generated by the shared ADPLL or a dedicated ADPLL. In some embodiments of the present invention, the ADPLL can operate in a power saving mode to reduce power consumption. For example, the ADPLL operates in a normal mode before locking and switches to the power saving mode after locking.

Memory banks 808 store software codes for the processors of the wireless communication device 80. Each processor executes software to implement the functions of the respective communication or application layer. For example, the PHY processor 816 includes a transmitting signal processing unit and a receiving signal processing unit and manages the interface with the wireless medium. The PHY processor 816 operates on PPDUs by exchanging digital samples with the radio module which comprises the RF transmitter 802, Digital-to-Analog Converters (DACs), the RF receiver 804, Analog-to-Digital Converters (ADCs) and digital filters. The MAC processor 814 executes MAC level instructions and manages the interface between the application software and the wireless medium, through the PHY processor 816. The MAC processor 814 is responsible for coordinating access to the wireless medium so that the AP and STAs in range can communicate effectively. The MAC processor 814 adds header and tail bytes to units of data provided by the higher levels and sends them to the PHY layer for transmission. The reverse happens when receiving data from the PHY layer. If a wireless frame is received in error, the MAC processor 814 manages the retransmission of the wireless frame. The HOST processor 818 interfaces with the MAC layer and is responsible for running high level functionalities of the wireless communication device 80. The peripheral bus 820 connects to a number of peripherals that support core functions of the wireless communication device 80, these peripherals may include timers, interrupts, radio/filters/system registers, counters, Universal Asynchronous Receiver-Transmitter (UART), General Purpose Input Output (GPIO) interfaces and others. The PHY processor 816, the MAC processor 814, the HOST processor 818, the peripheral bus 820, memory banks 808 and input/output interfaces 810, communicate with each other via the system bus 812. Memory banks 808 may further store an operating system and applications. The input/output interface unit 810 allows for the exchange of information with a user. The antenna unit 806 may include a single antenna or multiple antennas.

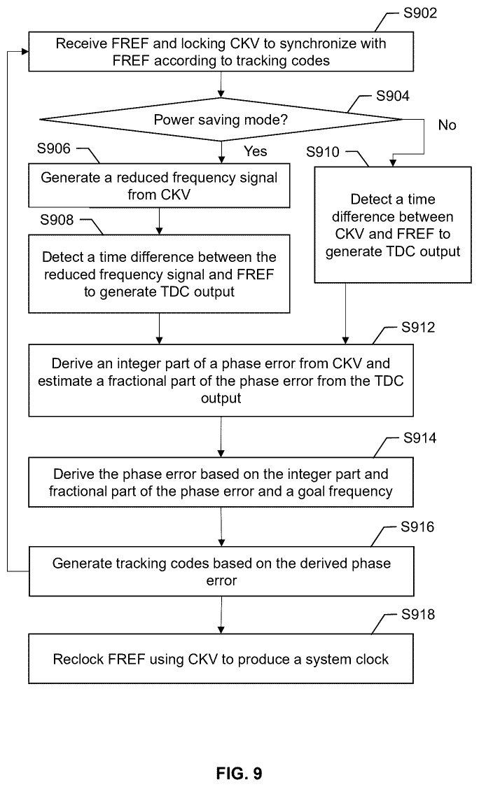

FIG. 9 is a flowchart illustrating an embodiment of a method for locking an oscillator output to synchronize with a reference clock by an ADPLL capable of operating in power saving mode. The ADPLL receives a reference clock signal (FREF) and locks a DCO output signal (CKV) to synchronize with FREF according to tracking codes in step S902 by a DCO. Step S904 determines whether the ADPLL is operating in power saving mode. Upon determining the ADPLL is operating in power saving mode, a reduced frequency signal is generated from CKV in step S906 and a time difference between the reduced frequency signal and FREF is detected to generate an TDC output in step S908. A time difference between CKV and FREF is detected to generate an TDC output in step S910 when the ADPLL is not operating in power saving mode. After the TDC output is generated in either step S908 or S910, an integer part of a phase error is derived from CKV, and a fractional part of the phase error is estimated from the TDC output in step S912. The phase error is derived based on the integer and fractional part of the phase error and a goal frequency in step S914, and this phase error is used to generate tracking codes in step S916. The tracking codes are fed back to the DCO and used to lock CKV in S902. In step S918, the ADPLL reclocks FREF using CKV to produce a system clock for the ADPLL.

Although the invention is illustrated and described herein with reference to specific embodiments, the invention is not intended to be limited to the details shown. Rather, various modifications may be made in the details within the scope and range of equivalents of the claims and without departing from the invention. It is to be understood that the above description is illustrative of the invention and is not to be construed as limiting the invention. Various modifications, applications and/or combinations of the embodiments may occur to those skilled in the art without departing from the scope of the invention as defined by the claims. Well-known circuits, processes, algorithms, structures, and techniques may be shown without unnecessary detail to avoid obscuring the aspects.

Processes and methods according to the above-described examples can be implemented using computer-executable instructions that are stored or otherwise available from computer-readable media. Such instructions can include, for example, instructions and data which cause or otherwise configure a general-purpose computer, special purpose computer, or a processing device to perform a certain function or group of functions. Portions of computer resources used can be accessible over a network. The computer executable instructions may be, for example, binaries, intermediate format instructions such as assembly language, firmware, source code, etc. Devices implementing processes and methods according to these disclosures can include hardware, software, firmware, middleware, microcode, hardware description languages, or any combination thereof, and can take any of a variety of form factors. When implemented in software, firmware, middleware, or microcode, the program code or code segments to perform the necessary tasks may be stored in a computer-readable or machine-readable medium. The computer-readable medium may comprise memory or data storage media, such as Random-Access Memory (RAM) such as Synchronous Dynamic Random-Access Memory (SDRAM), Read-Only Memory (ROM), Non-Volatile Random-Access Memory (NVRAM), Electrically Erasable Programmable Read-Only Memory (EEPROM), FLASH memory, magnetic or optical data storage media, and the like. The techniques additionally, or alternatively, may be realized at least in part by a computer-readable communication medium that carries or communicates program code in the form of instructions or data structures and that can be accessed, read, and/or executed by a computer, such as propagated signals or waves. The program code may be executed by a processor, which may include one or more processors, such as one or more Digital Signal Processors (DSPs), general purpose microprocessors, an Application Specific Integrated Circuits (ASICs), Field Programmable Logic Arrays (FPGAs), or other equivalent integrated or discrete logic circuitry. Such a processor may be configured to perform any of the steps described in this disclosure. A general-purpose processor may be a microprocessor; alternatively, the processor may be any conventional processor, controller, microcontroller, or state machine. A processor may also be implemented as a combination of computing devices.

To clearly illustrate the interchangeability of hardware and software, various illustrative components, blocks, modules, engines, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present application.

What is claimed is:

1. An all-digital phase locked loop (ADPLL), comprising:
a digitally controlled oscillator (DCO), generating a DCO output signal (CKV) to synchronize with a reference clock signal (FREF);
a counter, generating an integer part of a phase error from the DCO output signal;
a time to digital converter (TDC), detecting a time difference between a reduced frequency signal and the reference clock signal, wherein the reduced frequency signal is generated from the DCO output signal and has a lower frequency than a frequency of the DCO output signal;
a phase detector, receiving the integer part of the phase error from the counter and the time difference from the TDC, estimating a fractional part of the phase error based on the time difference, and deriving the phase error based on the integer part of the phase error, the fractional part of the phase error, and a goal frequency set by a frequency control word (FCW); and
a digital loop filter (DLF), receiving the phase error from the phase detector and providing tracking codes to the DCO;
wherein the DCO takes the tracking codes to adjust the frequency of the DCO output signal and lock the DCO output signal in synchronization with the reference clock signal.

2. The ADPLL of claim 1, further comprising a D-type flip flop (DFF) generating the reduced frequency signal from the DCO output signal and the reference clock signal, wherein the reduced frequency signal is a CKV snapshot signal carrying information of a rising edge of the DCO output signal with respect to each sampling point of the reference clock signal.

3. The ADPLL of claim 2, wherein the DFF generates the CKV snapshot signal by latching the DCO output signal using the reference clock signal to capture the rising edge of the DCO output signal subsequently after each rising edge of the reference clock signal.

4. The ADPLL of claim 3, wherein the phase detector detects a TDC rising edge (TDC′ RISE) from a TDC output and calculates the fractional part of the phase error by multiplying the TDC rising edge and a TDC gain (KTDC).

5. The ADPLL of claim 2, wherein the CKV snapshot signal captures the rising edge of the DCO output signal immediately preceding each sampling point of the reference clock signal.

6. The ADPLL of claim 5, wherein the phase detector detects a TDC rising edge (TDC_{RISE}) from a TDC output and calculates the fractional part of the phase error by one minus a multiplication of the TDC rising edge and a TDC gain (KTDC).

7. The ADPLL of claim 1, wherein the TDC detects a time difference between the DCO output signal and the reference clock signal when operating in a normal mode and the TDC detects a time difference between the reduced frequency signal and the reference clock signal when operating in a power saving mode.

8. The ADPLL of claim 7, wherein the TDC operates in the normal mode during an ADPLL locking process, and the TDC switches from the normal mode to the power saving mode once the ADPLL is locked.

9. The ADPLL of claim 7, wherein the phase detector comprises a fractional phase error estimation block, decoding a TDC output to identify a TDC falling edge (TDC_{FALL}) and a TDC rising edge (TDC_{RISE}), and computing the fractional part of the phase error based on the TDC falling edge and TDC rising edge when the TDC is operating in the normal mode.

10. The ADPLL of claim 9, wherein the fractional phase error estimation block estimates a TDC gain (KTDC) from the TDC falling edge and the TDC rising edge, derives a fixed TDC gain from the estimated TDC gain, and computes the fractional part of the phase error using the fixed TDC gain when the TDC is operating in the power saving mode.

11. The ADPLL of claim 10, wherein the fractional phase error estimation block derives the fixed TDC gain by averaging a predetermined number of previously estimated TDC gains.

12. The ADPLL of claim 1, wherein the TDC is composed of N-stage inverter chain, and the time difference detected by the TDC is an N-bit pseudo thermometer code.

13. The ADPLL of claim 12, wherein the phase detector comprises a thermometer decoder identifying a 1-to-0 bit transition in the N-bit pseudo thermometer code to generate a TDC rising edge (TDC′_{RISE}), and a multiplier multiplying the TDC rising edge with a TDC gain (KTDC) to generate the fractional part of the phase error.

14. The ADPLL of claim 13, wherein the reduced frequency signal is generated by capturing a rising edge of the DCO output signal after each sampling point of the reference clock signal, and the TDC rising edge generated by the thermometer decoder represents a time difference measured between a sampling point of the reference clock signal and the subsequent rising edge of the reduced frequency signal.

15. The ADPLL of claim 1, wherein the TDC comprises an input selection circuit dynamically selecting two TDC inputs from the reduced frequency signal and the reference clock signal or the DCO output signal and the reference clock signal depending on an enable signal; wherein TDC detects a time difference between the two TDC inputs selected by the input selection circuit.

16. The ADPLL of claim 1, further comprising a D-type flip flop (DFF) couple to the DCO to reclock the reference clock signal using the DCO output signal to produce a system clock for the ADPLL.

17. A method of clock locking by an all-digital phase locked loop (ADPLL) for a wireless communication device, comprising:
receiving a reference clock signal (FREF);
generating a digitally controlled oscillator (DCO) output signal (CKV) to synchronize with the reference clock signal based on tracking codes;
generating a reduced frequency signal from the DCO output signal, wherein the reduced frequency signal has a lower frequency than a frequency of the DCO output signal;
generating a time to digital converter (TDC) output by detecting a time difference between the reduced frequency signal and the reference clock signal;
deriving an integer part of a phase error from the DCO output signal and estimating a fractional part of the phase error based on the TDC output;
deriving the phase error based on the integer part of the phase error, the fractional part of the phase error, and a goal frequency set by a frequency control word (FCW); and
generating the tracking codes based on the derived phase error, wherein the tracking codes are used to adjust the frequency of the DCO output signal and lock the DCO output signal in synchronization with the reference clock signal.

18. The method of claim 17, wherein the step of generating a TDC output further comprises detecting a time difference between the reduced frequency signal and the reference clock signal when operating in a power saving mode and detecting a time difference between the DCO output signal and the reference clock signal when operating in a normal mode.

19. The method of claim 17, wherein the reduced frequency signal carries information of a rising edge of the DCO output signal with respect to each sampling point of the reference clock signal.

20. The method of claim 17, further comprising reclocking the reference clock signal using the DCO output signal to produce a system clock for the ADPLL.
